(19) United States
(12) Patent Application Publication
(10) Pub. No.: US 2011/0133757 A1
(43) Pub. Date: Jun. 9, 2011

(54) Apparatus and method for evaluating capacitor

(75) Inventors: Kyoung Soo Chae, Seoul (KR); Hyun Chul Jung, Yongin (KR); Hee Bum Lee, Suwon (KR)

(73) Assignee: SAMSUNG ELECTRO-MECHANICS CO., LTD., Suwon (KR)

(21) Appl. No.: 12/662,717

(22) Filed: Apr. 29, 2010

(30) Foreign Application Priority Data
Dec. 4, 2009 (KR) 10-2009-0119904

(51) Int. Cl. G01R 27/26

(52) U.S. Cl. 324/678

(57) ABSTRACT

There is provided an apparatus for evaluating a capacitor, including: a charge/discharge control unit 100 that controls charge and discharge, a charge/discharge switch 200 that selects a connection between a capacitor CSP to be measured and a power supply unit 50 or a connection between the capacitor CSP and a discharge path DP, a discharge unit 300 that is connected to the discharge path DP and provides discharge resistance for the discharge of the capacitor CSP, a voltage measuring unit 400 that measures the voltage of the capacitor CSP, a current measuring unit 500 that measures the charge current or discharge current of the capacitor CSP, and a main control unit 600 that controls the charge and discharge through the charge/discharge control unit 100 and obtains equivalent series resistance Res, capacitance C and self discharge resistance Rsd during the charge and discharge.

### CROSS-REFERENCE TO RELATED APPLICATIONS

This application claims the priority of Korean Patent Application No. 10-2009-0119904 filed on Dec. 4, 2009, in the Korean Intellectual Property Office, the disclosure of which is incorporated herein by reference.

### BACKGROUND OF THE INVENTION

1. Field of the Invention

The present invention relates to an apparatus and a method for evaluating a large capacity capacitor that can be applied to automobiles or wind power generation, and more particularly, to an apparatus and a method for evaluating a capacitor that can automatically measure the ESR (equivalent series resistance), capacitance and self discharge resistance of the capacitor, and rapidly perform the measurement.

2. Description of the Related Art

Recently, there has been increasing demand for a large capacity capacitor that features high output for hybrid automobiles, wind power generation, etc. Further, it is necessary to evaluate the characteristics of such a large capacity capacitor during the manufacturing or use thereof.

FIG. 1 is an equivalent circuit view of a capacitor to be measured. Referring to FIG. 1, a large capacity capacitor CSP may be represented by Equivalent Series Resistance (ESR) Res, capacitance C, and self discharge resistance Rsd.

The measurement of a capacitor according to the prior art is basically performed by measuring existing low capacity capacitance and self discharge rate. This is the reason that the value of the output current thereof is small enough to ignore the effect by the equivalent series resistance.

However, since the large capacity capacitor outputs current from several amperes to several hundred amperes, it cannot ignore voltage drop by equivalent series resistance, such that the large capacity capacitor cannot be evaluated by the method for measuring the small capacity capacitor according to prior art.

Further, it takes a long time (for example, 2-4 hours) for the large capacity capacitance to be charged once or to discharge charged voltage, such that the measurement evaluation time for judging pass/fail of a large capacity capacitor is inevitably increased as compared to that of the small capacity capacitor as the capacity of capacitors is increased.

As described above, it takes an excessive amount of time to measure the large capacity capacitor, which becomes an obstacle in the mass production thereof.

### SUMMARY OF THE INVENTION

An aspect of the present invention provides an apparatus and a method for evaluating a capacitor that can automatically measure the ESR, capacitance, and self discharge resistance of the capacitor and rapidly perform the measurement.

According to an aspect of the present invention, there is provided an apparatus for evaluating a capacitor, including: a charge/discharge control unit controlling charge and discharge; a charge/discharge switch selecting a connection between a capacitor to be measured and a power supply unit or a connection between the capacitor and a discharge path according to the charge/discharge control of the charge/discharge control unit; a discharge unit connected to the discharge path and providing discharge resistance for the discharge of the capacitor; a voltage measuring unit measuring the voltage of the capacitor; a current measuring unit measuring the charge current or discharge current of the capacitor; and a main control unit controlling the charge and discharge through the charge/discharge control unit and obtaining equivalent series resistance, capacitance and self discharge resistance based on the voltage of the capacitor, the charge current and the discharge current during the charge and discharge.

The main control unit obtains the equivalent series resistance by dividing a first error voltage corresponding to the differential voltage between full charge voltage at the time of the capacitor having a full charge and initial voltage of the capacitor after the charging of the capacitor is complete by the discharge current.

The main control unit obtains discharge resistance by dividing a second error voltage corresponding to the differential voltage between the initial voltage and predetermined set voltage by the discharge current, and obtains discharge time taken in dischanging the voltage of the capacitor from the initial voltage to the set voltage.

The main control unit obtains the capacitance by dividing the discharge time by the discharge resistance.

The main control unit measures the self discharge resistance by dividing the full charge voltage at the time of the capacitor having a full charge by the current obtained after the predetermined self discharge reference time after the capacitor is fully charged.

The main control unit further measures the self discharge rate through the ratio of the discharge voltage after the predetermined self discharge reference time and the full charge voltage at the time of the capacitor having a full charge.

The self discharge reference time may be set to a time that current is not flowing after the capacitor is completely discharged, in a normal state.

The main control unit obtains a voltage discharge linear approximation by detecting voltage dropped from the initial voltage at predetermined time intervals and by a predetermined number of times after the discharge starts, and obtains the discharge time using the voltage discharge linear approximation.

The discharge unit includes a parallel resistor circuit unit including a plurality of parallel resistors; and a switch circuit unit including a plurality of switches selecting each of the plurality of parallel resistors of the parallel resistor circuit unit.

According to another aspect of the present invention, there is provided a method for evaluating a capacitor, including: charging a capacitor to be measured; measuring full charge voltage and current when the charging of the capacitor is complete; performing discharge after the charging is complete; measuring initial voltage and discharge current when the discharge starts; calculating equivalent series resistance using the initial voltage and the discharge current; calculating discharge time taken in dischanging the voltage of the capacitor from the initial voltage to a predetermined set voltage; and calculating capacitance and self discharge resistance using the initial voltage, the predetermined set voltage, the discharge current, and the discharge time.

The calculating of the equivalent series resistance includes obtaining the equivalent series resistance by dividing a first error voltage corresponding to the differential voltage between full charge voltage at the time of the capacitor having a full charge and the initial voltage of the capacitor after the charging of the capacitor is complete by the discharge current.

The calculating of the capacitance and self discharge resistance includes obtaining discharge resistance by dividing a second error voltage corresponding to the differential voltage between the initial voltage and a predetermined set voltage by the discharge current, and obtaining discharge time taken in dischanging the voltage of the capacitor from the initial voltage to the set voltage.

The calculating of the capacitance and self discharge resistance includes obtaining the capacitance by dividing the discharge time by the discharge resistance.

The calculating of the capacitance and self discharge resistance includes measuring the self discharge resistance by dividing the full charge voltage at the time of the capacitor having a full charge by the current obtained after the predetermined self discharge reference time after the capacitor is fully charged.

The calculating of the capacitance and self discharge resistance includes further measuring self discharge rate through the ratio of the discharge voltage after the predetermined self discharge reference time and the full charge voltage at the time of the capacitor having a full charge.

The self discharge reference time is set as a time that current is not flowing after the capacitor is completely discharged, in a normal state.

The calculating of the capacitance and self discharge resistance includes obtaining a voltage discharge linear approximation by detecting voltage dropped from the initial voltage at predetermined time intervals and predetermined number of times after the discharge starts, and obtaining the discharge time taken in dischanging the voltage of the capacitor from the initial voltage to the set voltage using the voltage discharge linear approximation.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is an equivalent circuit view of a capacitor to be measured;

FIG. 2 is a block diagram of an apparatus for evaluating a capacitor according to an exemplary embodiment of the present invention;

FIG. 3 is a curve diagram illustrating charge/discharge characteristics of a capacitor to be measured in the exemplary embodiment of the present invention;

FIG. 4 is a discharge voltage linear characteristics graph according to an exemplary embodiment of the present invention;

FIG. 5 is a circuit view of a discharge unit according to an exemplary embodiment of the present invention; and

FIG. 6 is a flowchart showing a method for evaluating a capacitor according to an exemplary embodiment of the present invention.

### DETAILED DESCRIPTION OF THE PREFERRED EMBODIMENT

Exemplary embodiments of the present invention will now be described in detail with reference to the accompanying drawings.

The present invention should not be construed as being limited to the embodiments set forth herein and the embodiments may be used to help understanding of the technical idea of the present invention. Like reference numerals designate like components having substantially the same constitutions and functions throughout the drawings of the present invention.

FIG. 2 is a block diagram of an apparatus for evaluating a capacitor according to an exemplary embodiment of the present invention. Referring to FIG. 2, an apparatus for evaluating a capacitor according to an exemplary embodiment of the present invention may be configured to include a charge/discharge control unit 100 that controls charge and discharge, a charge/discharge switch 200 that selects a connection between a capacitor CSP to be measured and a power supply unit 50 or a connection between the capacitor CSP and a discharge path DP according to the charge/discharge control of the charge/discharge control unit 100, a discharge unit 300 that is connected to the discharge path DP and provides discharge resistance for the discharge of the capacitor CSP, a voltage measuring unit 400 that measures the voltage of the capacitor CSP, a current measuring unit 500 that measures the charge current or discharge current of the capacitor CSP, and a main control unit 600 that controls the charge and discharge through the charge/discharge control unit 100 and obtains equivalent series resistance Res, capacitance C and self discharge resistance Rsd based on the voltage, the charge current and the discharge current of the capacitor CSP during charge and discharge.

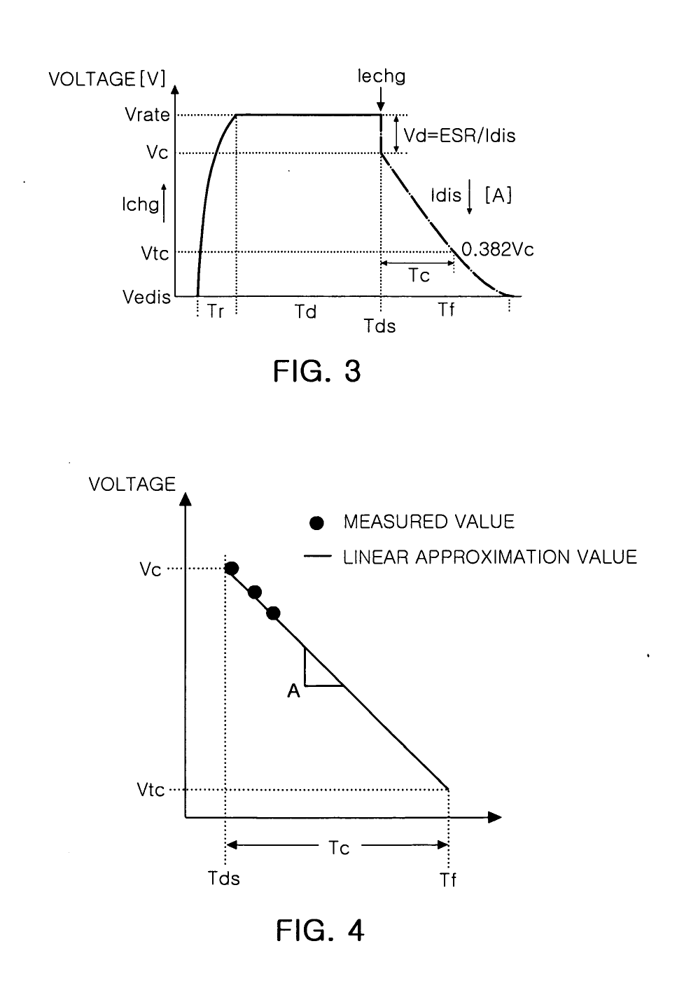

FIG. 3 is a curve diagram illustrating charge/discharge characteristics of a capacitor to be measured in the exemplary embodiment of the present invention. In FIG. 3, Vedis is discharge complete voltage, Vtc is set voltage, Ichg is charge current, Vc is initial voltage, Vrate is full charge voltage, lechg is charge complete current, Vd is first error voltage, ldis is discharge current, Tr is charge time, Td is charge maintenance time, Tds is discharge start time point, Tf is a predetermined final discharge time, and Tc is discharge time.

The main control unit 600 is configured to obtain the equivalent series resistance Res by dividing the first error voltage Vd corresponding to differential voltage between the full charge voltage Vrate at the time of the capacitor CSP having a full charge and the initial voltage Vc of the capacitor CSP after the charging of the capacitor is complete by the discharge current ldis.

Referring to FIGS. 2 and 3, the main control unit 600 is configured to obtain the discharge resistance Rtc by dividing the second error voltage Vd2 corresponding to the differential voltage between the initial voltage Vc and the predetermined set voltage Vtc by the discharge current ldis, and obtain the discharge time Tc taken in dischanging the voltage of the capacitor CSP from the initial voltage Vc to the set voltage Vtc.

The main control unit 600 is configured to obtain the capacitance C by dividing the discharge time Tc by the discharge resistance Rtc.

The main control unit 600 is configured to obtain the self discharge resistance Rsd by dividing the full charge voltage Vrate at the time the capacitor CSP having a full charge by the current ldis obtained after the predetermined self discharge reference time after the capacitor is fully charged.

The main control unit 600 may be configured to obtain a self discharge rate through the ratio of the discharge voltage Vdis after the predetermined self discharge reference time and the full charge voltage Vrate at the time of the capacitor CSP having a full charge.

At this time, the self discharge reference time may be set to a time that current is not flowing after the capacitor C is completely discharged, in a normal state.

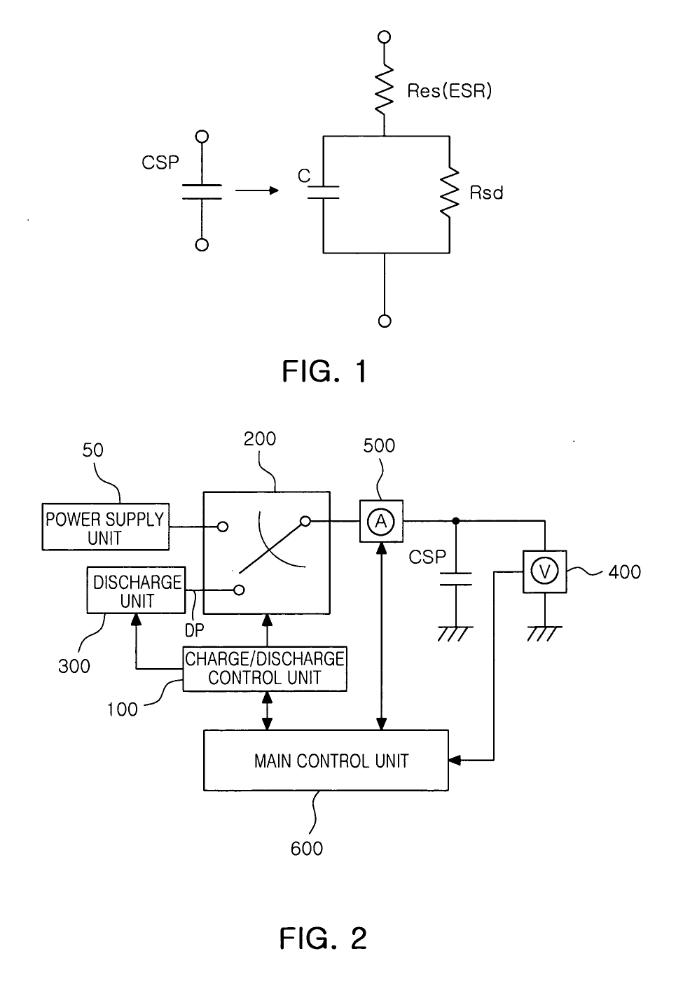

FIG. 4 is a discharge voltage linear characteristics graph according to an exemplary embodiment of the present invention. Referring to FIGS. 1 through 4, the main control unit 600 may be configured to obtain a voltage discharge linear approximation by detecting voltage dropped from the initial voltage Vc at predetermined time intervals and predetermined number of times after the discharge starts, and obtain the discharge time Tc using the voltage discharge linear approximation.

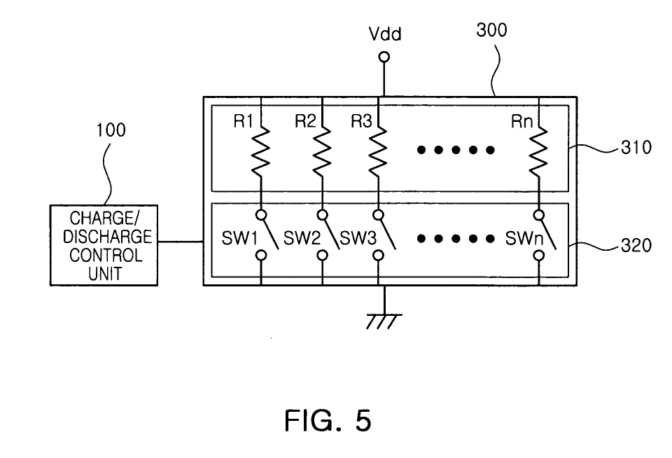

FIG. 5 is a circuit view of a discharge unit according to an exemplary embodiment of the present invention. Referring to FIG. 5, the discharge unit 300 may be configured to include a parallel resistor circuit unit 310 that includes a plurality of parallel resistors and a switch circuit unit 320 that includes a plurality of switches SW1˜SWn selecting each of the plurality of parallel resistors R1˜Rn of the parallel resistor circuit unit 310.

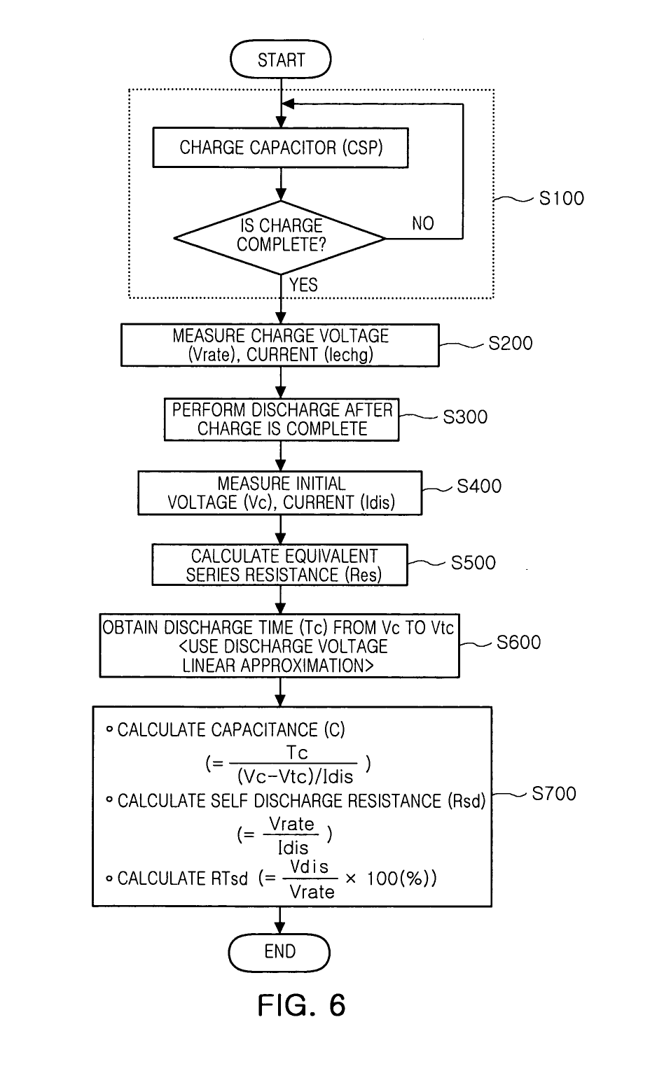

FIG. 6 is a flowchart showing a method for evaluating a capacitor according to an exemplary embodiment of the present invention. Referring to FIG. 6, the method for evaluating the capacitor according to an exemplary embodiment of the present invention may be configured to include charging a capacitor CSP to be measured (S100), measuring full charge voltage Vrate and current lechg when the charging of the capacitor CSP is complete (S200), performing discharge after the charge is complete (S300), measuring initial voltage Vc and discharge current ldis when the discharge starts (S400), calculating equivalent series resistance Res using the initial voltage Vc and the discharge current ldis (S500), calculating discharge time Tc taken in dischanging the voltage of the capacitor from the initial voltage Vc to predetermined set voltage Vtc (S600), and calculating capacitance C and self discharge resistance Rsd using the initial voltage Vc, the predetermined set voltage Vtc, the discharge current ldis, and the discharge time Tc (S700).

The calculating of the equivalent series resistance Res (S500) includes obtaining the equivalent series resistance Res by dividing a first error voltage Vd corresponding to the differential voltage between the full charge voltage Vrate at the time of the capacitor CSP having a full charge and the initial voltage Vc of the capacitor CSP after the charging of the capacitor is complete by the discharge current ldis.

The calculating of the capacitance C and the self discharge resistance Rsd (S600) includes obtaining a discharge resistance Rtc by dividing the second error voltage Vd2 corresponding to differential voltage between the initial voltage Vc and the predetermined set voltage Vtc by the discharge current ldis, and obtaining the discharge time Tc taken in dischanging the voltage of the capacitor CSP from the initial voltage Vc to the set voltage Vtc.

The calculating of the capacitance C and the self discharge resistance Rsd (S700) includes obtaining the capacitance C by dividing the discharge time Tc by the discharge resistance Rtc.

The calculating of the capacitance C and the self discharge resistance Rsd (S700) includes obtaining the self discharge resistance Rsd by dividing the full charge voltage Vrate at the time of the capacitor CSP having a full charge by the current ldis obtained after the predetermined self discharge reference time after the capacitor is fully charged.

The calculating of the capacitance C and the self discharge resistance Rsd (S700) may include obtaining a self discharge rate through the ratio of the discharge voltage Vdis after the predetermined self discharge reference time and the full charge voltage Vrate at the time of the capacitor CSP having a full charge.

At this time, the self discharge reference time may be set to a time that current is not flowing after the capacitor C is completely discharged, in a normal state.

The calculating of the capacitance C and the self discharge resistance Rsd (S700) may include obtaining a voltage discharge linear approximation by detecting voltage dropped from the initial voltage Vc at predetermined time intervals and a predetermined number of times after the discharge starts, and obtaining the discharge time Tc taken in dischanging the voltage of the capacitor CSP from the initial voltage Vc to the set voltage Vtc using the voltage discharge linear approximation.

Hereinafter, the actions and effects of the present invention will be described in detail with reference to the accompanying drawings.

The apparatus for evaluating the capacitor according to the present invention will now be described with reference to FIGS. 2 through 5. Referring first to FIG. 2, the charge/discharge control unit 100 of the apparatus for evaluating the capacitor of the present invention controls charge according to the control of the main control unit 600 of the present invention.

The charge/discharge switch 200 selects a connection between the capacitor CSP to be measured and the power supply unit 50 according to the charge control of the charge/discharge control unit 100.

Therefore, the capacitor CSP is charged by power supplied from the power supply unit 50, such that during the charge, the voltage measuring unit 400 of the present invention measures the voltage of the capacitor CSP to provide it to the main control unit 600 and the current measuring unit 500 of the present invention measures the current of the capacitor CSP to provide it to the main control unit 600.

The main control unit 600 monitors the voltage from the voltage measuring unit 400 and the current from the current measuring unit 500 and determines whether the capacitor CSP is fully charged. If it is determined that the capacitor CSP is fully charged, the main control unit 600 stores the full charge voltage Vrate and the current lechg.

Referring to FIGS. 2 and 3, the main control unit 600 determines that the capacitor CSP is fully charged when the charge voltage of the capacitor CSP is not further raised and is maintained for a predetermined time.

Thereafter, the main control unit 600 controls the discharge through the charge/discharge control unit 100, wherein the charge/discharge control unit 100 controls the charge/discharge switch 200 to perform the discharge. Therefore, the charge/discharge switch 200 connects the capacitor CSP to the discharge unit 300 through the discharge path DP, such that the voltage charged in the capacitor CSP is discharged through the discharge unit 300.

During the discharge, the voltage measuring unit 400 of the present invention measures the voltage of the capacitor CSP to provide it to the main control unit 600 and the current measuring unit 500 of the present invention measures current during the discharge of the capacitor CSP to provide it to the main control unit 600.

Therefore, the voltage of the capacitor is momentarily dropped from the full charge voltage to the initial voltage Vc at the discharge starting time point, wherein the main control unit 600 stores the initial voltage Vc measured by the voltage measuring unit 400 and the discharge current ldis measured by the current measuring unit 500.

The main control unit 600 monitors the discharge voltage from the voltage measuring unit 400 and the discharge current from the current measuring unit 500 and determines whether the voltage of the capacitor CSP has reached the predetermined set voltage Vtc. If the main control unit 600 determines that the voltage of the capacitor CSP has reached the predetermined set voltage Vtc, it stores the discharge time Tc corresponding to the time required for the voltage to reach from the discharge starting time point Tds to the set voltage Vtc.

Thereafter, the main control unit 600 obtains the equivalent series resistance Res, the capacitance C, and the self discharge resistance Rsd based on the voltage, the charge current and the discharge current of the capacitor CSP.

More specifically, the main control unit 600 may first obtain the equivalent series resistance Res by dividing the first error voltage Vd corresponding to differential voltage between the full charge voltage Vrate at the time of the capacitor CSP having a full charge and the initial voltage Vc of the capacitor CSP after the charging of the capacitor is complete by the discharge current ldis, as represented by the following Equation 1.

Res[equivalent series resistance=ESR]=(Vrate−Vc)/Idis=Vd/Idis Equation 1

Then, the main control unit 600 obtains the discharge resistance Rtc by dividing a second error voltage Vd2 corresponding to the differential voltage between the initial voltage Vc and the predetermined set voltage Vtc by the discharge current ldis, and obtains the discharge time Tc taken in dischanging the voltage of the capacitor CSP from the initial voltage Vc to the set voltage Vtc.

The main control unit 600 may obtain the capacitance C by dividing the discharge time Tc by the discharge resistance Rtc, as represented by the following Equation 2.

C[Capacitance]=Tc/[(Vc−Vtc)/Idis]=Tc/[Vd2/Idis]=Tc/Rtc Equation 2

Then, the main control unit 600 may obtain the self discharge resistance Rsd by dividing the full charge voltage Vrate at the time of the capacitor CSP having a full charge by the current ldis obtained after the predetermined self discharge reference time after the capacitor is fully charged, as represented by the following Equation 3.

Rsd[self discharge resistance]=Vrate/Idis Equation 3

Further, the main control unit 600 may obtain the self discharge rate through the ratio of the discharge voltage Vdis after the predetermined self discharge reference time and the full charge voltage Vrate at the time of the capacitor CSP having a full charge as represented by the following Equation 4.

At this time, the self discharge reference time may be set to a time that current is not flowing after the capacitor C is completely discharged, in a normal state.

RTsd(self discharge rate)=(Vrate/Vdis)×100(%) Equation 4

Referring to FIGS. 2, 3, and 4, the main control unit 600 may obtain a voltage discharge linear approximation by detecting voltage dropped from the initial voltage Vc at predetermined time intervals and predetermined number of times after the discharge starts, as represented by the following Equation 5, and obtain the discharge time Tc using the voltage discharge linear approximation.

Y=A·X+B Equation 5

In Equation 5, Y is voltage, X is time, A is gradient, and B is Y-axis intercept. Referring to the above Equation 5, the discharge time Tc taken in reducing the voltage from Vc to Vtc may be derived from the discharge voltage linear approximation.

Referring to FIG. 5, at least one of the plurality of parallel resistors R1 to Rn of the parallel resistor circuit unit 310 may be selected by the plurality of switches SW1 to SWn of the switch circuit unit 320 of the discharge unit 300.

Therefore, the present invention can select resistive value contributing to the discharge of the discharge unit 300, thereby making it possible to properly control discharge velocity according to the characteristics of the capacitor to be measured.

Hereinafter, a method for evaluating a capacitor according to an exemplary embodiment of the present invention will be described with reference to FIGS. 2, 3, 4 and 6.

First, referring to FIG. 6, in the method for evaluating the capacitor according to an exemplary embodiment of the present invention, the capacitor CSP to be measured is charged (S100).

That is, when the charge/discharge control unit 100 controls the charge according to the control of the main control unit 600, the charge/discharge switch 200 selects the connection between the capacitor CSP to be measured and the power supply unit 50. Therefore, the capacitor CSP is charged by the power supply supplied from the power supply unit 50.

Then, when the charging of the capacitor CSP is complete, the full charge voltage Vrate and the current lechg are measured (S200).

That is, the main control unit 600 monitors the voltage from the voltage measuring unit 400 and the current from the current measuring unit 500 and determines whether the capacitor CSP is fully charged. If it is determined that the capacitor CSP is fully charged, the main control unit 600 measures and stores the full charge voltage Vrate and the current lechg.

At this time, as previously mentioned, the main control unit 600 determines that the capacitor CSP is fully charged when the charge voltage of the capacitor CSP is not further raised and is maintained for a predetermined time.

Then, the discharge is performed after the charge is complete (S300) and the initial voltage Vc and the discharge current ldis at the time of discharge start are measured (S400).

That is, when the charge/discharge control unit 100 controls the charge/discharge switch 200 to perform the discharge according to the control of the main control unit 600, the charge/discharge switch 200 connects the capacitor CSP to the discharge unit 300 through the discharge path DP to discharge the voltage of the capacitor CSP through the discharge unit 300.

At this time, the capacitor is momentarily dropped from the full charge voltage to the initial voltage Vc at the time of discharge starting time point, wherein the main control unit 600 stores the initial voltage Vc measured by the voltage measuring unit 400 and the discharge current ldis measured by the current measuring unit 500.

Then, the equivalent series resistance Res is calculated using the initial voltage Vc and the discharge current ldis (S500).

For example, the equivalent series resistance may be obtained by dividing the first error voltage Vd corresponding to differential voltage between the full charge voltage Vrate at the time of the capacitor CSP having a full charge and the initial voltage Vc of the capacitor CSP after the charging of the capacitor is complete by the discharge current ldis, as represented by the Equation 1.

Then, the discharge time Tc taken in dischanging the voltage of the capacitor from the initial voltage Vc to the predetermined set voltage Vtc is calculated (S600).

Then, the capacitance C and the self discharge resistance Rsd are calculated using the initial voltage Vc, the predetermined set voltage Vtc, the discharge current ldis, and the discharge time Tc (S700).

For example, the discharge resistance Rtc may be obtained by dividing the second error voltage Vd2 corresponding to differential voltage between the initial voltage Vc and the predetermined set voltage Vtc by the discharge current ldis, and the discharge time Tc taken in dischanging the voltage of the capacitor CSP from the initial voltage Vc to the set voltage Vtc may be obtained (S700).

Therefore, the capacitance C may be obtained by dividing the discharge time Tc by the discharge resistance Rtc, as represented by the Equation 2.

Continuously, the self discharge resistance Rsd may be obtained by dividing the full charge voltage Vrate at the time of full charge by the current ldis after the predetermined self discharge reference time after the capacitor is fully charged (S700), as represented by the Equation 3.

That is, although the charge current should be ideally reduced to 0 at the time of full charge, the charge current having a predetermined value or more is flowing as the self discharge is generated by the self discharge resistance Rsd. Therefore, when the charge current and the discharge current is measured after a predetermined time elapses and the resistance is obtained by using Ohm's law, the self discharge resistance Rsd can be calculated.

Further, the self discharge rate RTsd may be obtained through the ratio of the discharge voltage Vdis after the predetermined self discharge reference time and the full charge voltage Vrate at the time of the capacitor CSP (S700) having a full charge, as represented by Equation 4.

Herein, the self discharge reference time may be set to a time that current is not flowing after the capacitor C is completely discharged, in a normal state.

At this time, when the voltage of the capacitor does not reach the full charge voltage Vrate for a predetermined time or the charge current lchg does not fall below the set value, it may be considered to have large self discharge rate and be determined as the defects of the capacitor.

Meanwhile, referring to to FIG. 4, the voltage discharge linear approximation may be obtained by detecting voltage dropped from the initial voltage Vc at predetermined time intervals and predetermined number of times after the discharge starts, as represented by the Equation 5, and the discharge time Tc taken in dischanging the voltage of the capacitor from the initial voltage Vc to the set voltage Vtc may be obtained using the voltage discharge linear approximation (S700).

Meanwhile, as another method for measuring the ESR when the discharge unit is disconnected from the capacitor during the discharge, the voltage of the capacitor is raised. This phenomenon is generated since the current is not output from the capacitor and thus the voltage drop by the ESR (equivalent series resistance) is not generated.

The resistance value may be derived by dividing the voltage increase by the current variation to thereby make the resistance value become the ESR.

As set forth above, according to exemplary embodiments of the present invention, the ESR (equivalent series resistance), the capacitance, and the self discharge resistance of the large capacity capacitor can be automatically and rapidly measured using the discharge voltage linear approximation.

While the present invention has been shown and described in connection with the exemplary embodiments, it will be apparent to those skilled in the art that modifications and variations can be made without departing from the spirit and scope of the invention as defined by the appended claims.

What is claimed is:

1. An apparatus for evaluating a capacitor, comprising:
a charge/discharge control unit controlling charge and discharge;
a charge/discharge switch selecting a connection between a capacitor to be measured and a power supply unit or a connection between the capacitor and a discharge path according to the charge/discharge control of the charge/discharge control unit;
a discharge unit connected to the discharge path and providing discharge resistance for the discharge of the capacitor;
a voltage measuring unit measuring the voltage of the capacitor;
a current measuring unit measuring the charge current or discharge current of the capacitor; and
a main control unit controlling the charge and discharge through the charge/discharge control unit and obtaining equivalent series resistance, capacitance and self discharge resistance based on the voltage of the capacitor, the charge current and the discharge current during the charge and discharge.

2. The apparatus for evaluating the capacitor of claim 1, wherein the main control unit obtains the equivalent series resistance by dividing a first error voltage corresponding to the differential voltage between full charge voltage at the time of the capacitor having a full charge and initial voltage of the capacitor after the charging of the capacitor is complete by the discharge current.

3. The apparatus for evaluating the capacitor of claim 1, wherein the main control unit obtains discharge resistance by dividing a second error voltage corresponding to the differential voltage between the initial voltage and predetermined set voltage by the discharge current, and obtains discharge time taken in dischanging the voltage of the capacitor from the initial voltage to the set voltage.

4. The apparatus for evaluating the capacitor of claim 3, wherein the main control unit obtains the capacitance by dividing the discharge time by the discharge resistance.

5. The apparatus for evaluating the capacitor of claim 1, wherein the main control unit measures the self discharge resistance by dividing the full charge voltage at the time of the capacitor having a full charge by the current obtained after the predetermined self discharge reference time after the capacitor is fully charged.

6. The apparatus for evaluating the capacitor of claim 5, wherein the main control unit further measures a self discharge rate through the ratio of the discharge voltage after the predetermined self discharge reference time and the full charge voltage at the time of the capacitor having a full charge.

7. The apparatus for evaluating the capacitor of claim 6, wherein the self discharge reference time may be set to a time that current is not flowing after the capacitor is completely discharged, in a normal state.

8. The apparatus for evaluating the capacitor of claim 3, wherein the main control unit obtains a voltage discharge linear approximation by detecting voltage dropped from the initial voltage at predetermined time intervals and by a predetermined number of times after the discharge starts, and obtains the discharge time using the voltage discharge linear approximation.

9. The apparatus for evaluating the capacitor of claim 1, wherein the discharge unit includes
a parallel resistor circuit unit including a plurality of parallel resistors; and
a switch circuit unit including a plurality of switches selecting each of the plurality of parallel resistors of the parallel resistor circuit unit.

10. A method for evaluating a capacitor, comprising:
charging a capacitor to be measured;
measuring full charge voltage and current when the charging of the capacitor is complete;
performing discharge after the charging is complete;
measuring initial voltage and discharge current when the discharge starts;
calculating equivalent series resistance using the initial voltage and the discharge current;
calculating discharge time taken in dischanging the voltage of the capacitor from the initial voltage to a predetermined set voltage; and
calculating capacitance and self discharge resistance using the initial voltage, the predetermined set voltage, the discharge current, and the discharge time.

11. The method for evaluating the capacitor of claim 10, wherein the calculating of the equivalent series resistance comprises obtaining the equivalent series resistance by dividing a first error voltage corresponding to the differential voltage between full charge voltage at the time of the capacitor having a full charge and the initial voltage of the capacitor after the charging of the capacitor is complete by the discharge current.

12. The method for evaluating the capacitor of claim 10, wherein the calculating of the capacitance and self discharge resistance comprises obtaining discharge resistance by dividing a second error voltage corresponding to the differential voltage between the initial voltage and a predetermined set voltage by the discharge current, and obtaining discharge time taken in dischanging the voltage of the capacitor from the initial voltage to the set voltage.

13. The method for evaluating the capacitor of claim 12, wherein the calculating of the capacitance and self discharge resistance comprises obtaining the capacitance by dividing the discharge time by the discharge resistance.

14. The method for evaluating the capacitor of claim 10, wherein the calculating of the capacitance and self discharge resistance includes measuring the self discharge resistance by dividing the full charge voltage at the time of the capacitor having a full charge by the current obtained after the predetermined self discharge reference time after the capacitor is fully charged.

15. The method for evaluating the capacitor of claim 14, wherein the calculating of the capacitance and self discharge resistance comprises further measuring self discharge rate through the ratio of the discharge voltage after the predetermined self discharge reference time and the full charge voltage at the time of the capacitor having a full charge.

16. The method for evaluating the capacitor of claim 15, wherein the self discharge reference time is set to a time that current is not flowing after the capacitor is completely discharged, in a normal state.

17. The method for evaluating the capacitor of claim 12, wherein the calculating of the capacitance and self discharge resistance comprises obtaining a voltage discharge linear approximation by detecting voltage dropped from the initial voltage at predetermined time intervals and by a predetermined number of times after the discharge starts, and obtaining the discharge time taken in dischanging the voltage of the capacitor from the initial voltage to the set voltage using the voltage discharge linear approximation.
